(19) United States
(12) Patent Application Publication
(10) Pub. No.: US 2025/0108475 A1
(43) Pub. Date: Apr. 3, 2025

(54) POLISHING APPARATUS AND POLISHING METHOD USING THE SAME

(71) Applicant: TAIWAN SEMICONDUCTOR MANUFACTURING COMPANY, LTD., Hsinchu (TW)

(72) Inventors: Jin-Hao JHANG, Hsinchu County (TW); James June Fan HSU, New Taipei City (TW); Wei-Yen WOON, Taoyuan City (TW)

(73) Assignee: TAIWAN SEMICONDUCTOR MANUFACTURING COMPANY, LTD., Hsinchu (TW)

(21) Appl. No.: 18/418,142

(22) Filed: Jan. 19, 2024

Related U.S. Application Data
(63) Continuation-in-part of application No. 18/477,399, filed on Sep. 28, 2023.

(51) Int. Cl. B24B 37/013; H01L 21/306; H01L 21/66

(52) U.S. Cl. CPC B24B 37/013; H01L 21/30625; H01L 22/26

(57) ABSTRACT

A method includes providing a wafer including a layer; performing a surface treatment to the layer; polishing the layer using a polishing pad; determining whether a surface roughness or a thickness of the layer reaches a pre-determined condition; and stopping polishing the layer when the surface roughness or the thickness of the layer reaches the pre-determined condition.

### PRIORITY CLAIM AND CROSS-REFERENCE

The present application is a continuation-in-part of U.S. application Ser. No. 18/477,399, filed on Sep. 28, 2023, which is herein incorporated by reference in its entirety.

### BACKGROUND

Chemical mechanical polishing (CMP) is a widely used process by which both chemical and mechanical forces are used to globally planarize a semiconductor workpiece. The planarization prepares the workpiece for the formation of a subsequent layer. A typical CMP tool includes a rotating platen covered by a polishing pad. A workpiece is then brought into contact with the rotating polishing pad to planarize the workpiece. CMP is a favored process because it achieves global planarization across the entire wafer surface. The CMP process polishes and removes materials from the wafer, and works on multi-material surfaces.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a CMP apparatus in accordance with some embodiments.

FIG. 1B is a side view of the CMP apparatus in FIG. 1A.

FIG. 2 is a flow chart of a method of a polishing process according to some embodiments.

FIGS. 3-9 illustrate top views and cross-sectional views of intermediate stages in the polishing process in accordance with some embodiments of the present disclosure.

FIG. 10A is a schematic view of a CMP apparatus in accordance with some embodiments.

FIG. 10B is a side view of the CMP apparatus in FIG. 10A.

FIG. 11 is a flow chart of a method of a polishing process according to some embodiments.

FIG. 12A is a schematic view of a CMP apparatus in accordance with some embodiments.

FIG. 12B is a side view of the CMP apparatus in FIG. 12A.

FIG. 13 is a flow chart of a method of a polishing process according to some embodiments.

FIG. 14 is a side view of a CMP system in accordance with some embodiments.

FIG. 15 is a flow chart of a method of a polishing process according to some embodiments.

FIGS. 16-19 illustrate cross-sectional views of intermediate stages in the formation of a semiconductor device in accordance with some embodiments of the present disclosure.

FIGS. 20-23 illustrate cross-sectional views of intermediate stages in the formation of a semiconductor device in accordance with some embodiments of the present disclosure.

FIG. 24 a schematic diagram illustrating a computer system in accordance with some embodiments of the present disclosure.

FIG. 25 is a schematic view of a CMP apparatus in accordance with some embodiments.

FIGS. 26A and 26B illustrate cross-sectional views of intermediate stages in the formation of a semiconductor device in accordance with some embodiments of the present disclosure.

FIGS. 27A, 27B, and 27C illustrate different methods for detecting surface roughness of a target layer in accordance with some embodiments of the present disclosure.

FIG. 28 illustrates a method for detecting thickness of a target layer in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The present disclosure is related to chemical mechanical polishing (CMP) apparatus and methods of using the same. More particularly, some embodiments of the present disclosure are related to CMP apparatuses including a beam device to modify the physical and/or chemical property of a top of a layer intended to be polished.

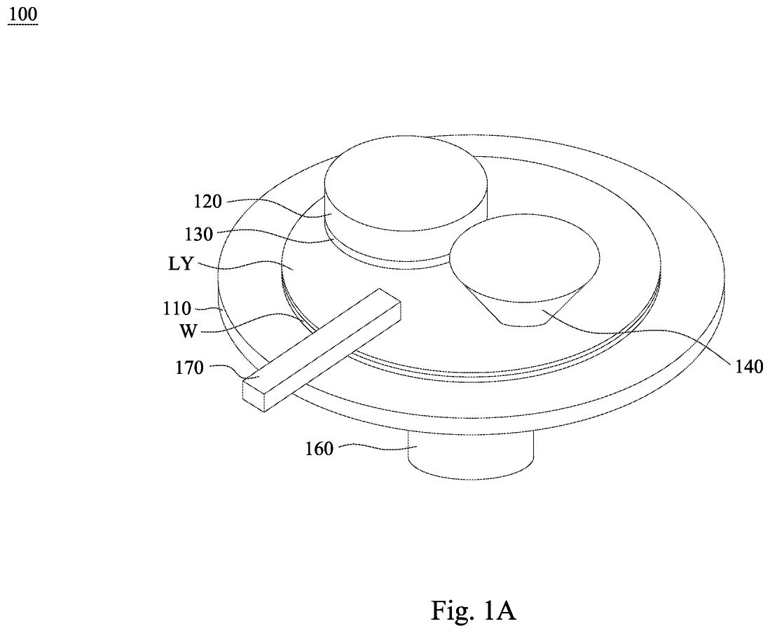

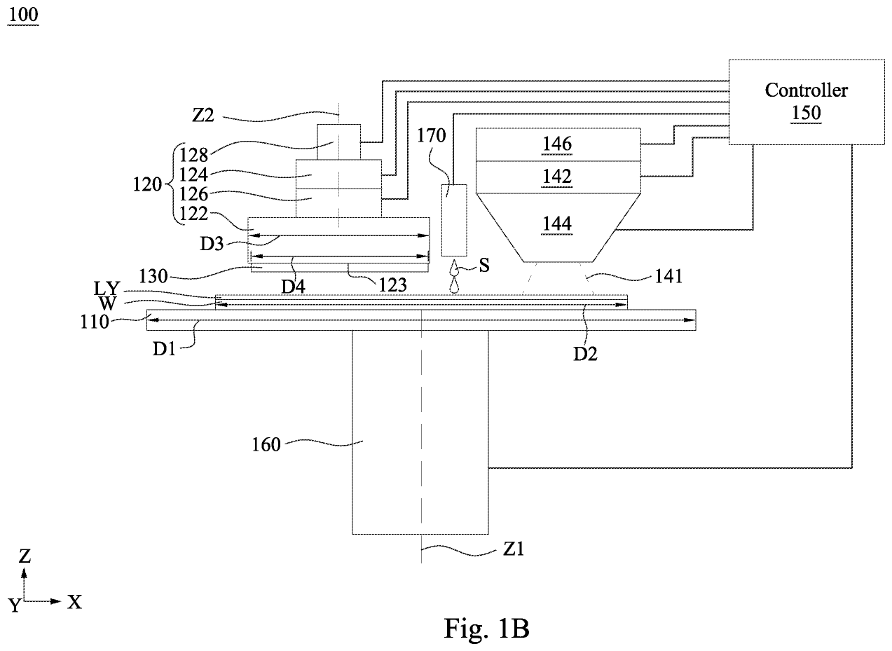

FIG. 1A is a schematic view of a CMP apparatus 100 in accordance with some embodiments, and FIG. 1B is a side view of the CMP apparatus 100 in FIG. 1A. The CMP apparatus 100 is configured to perform a CMP process on a wafer W in a semiconductor manufacturing process. The CMP apparatus 100 includes a platen 110, a pad holder 120, a polishing pad 130, a beam device 140, and a controller 150. The platen 110 is configured to secure a workpiece (e.g., a wafer W) during the CMP process. Therefore, the layer LY intended to be polished over the wafer W faces upward. The pad holder 120 and the beam device 140 are over the platen 110. The pad holder 120 is configured to hold the polishing pad 130. For example, the polishing pad 130 is fixed on a bottom surface 123 of the pad holder 120, and the pad holder 120 faces downward. Therefore, the polishing pad 130 is between the pad holder 120 and the platen 110 (or the wafer W), and the wafer W is between the polishing pad 130 and the platen 110.

As shown in FIG. 1B, the beam device 140 includes a beam source 142, a beam emitter 144, and a first moving mechanism 146. The beam emitter 144 is connected to the beam source 142. The first moving mechanism 146 is configured to move the beam emitter 144. The controller 150 is electrically connected to the beam source 142, the beam emitter 144, and the first moving mechanism 146.

The beam source 142 is a light source (e.g., a laser source) or a plasma source to produce a beam 141 for a surface treatment (e.g., laser beam or plasma beam). The beam emitter 144 may be a switch or the like. The beam 141 emits from the beam emitter 144 and projects downwardly. The controller 150 is configured to control the power and/or the pulse of the beam source 142. Further, the controller 150 controls the emitting and duration of the beam 141. In some embodiments, the beam 141 is able to move relative to the wafer W by using the first moving mechanism 146. The controller 150 further controls the first moving mechanism 146 to move the position of the beam emitter 144 along X, Y, and Z axes. During the polishing process, the beam device 140 emits or projects the beam 141 to the wafer W to break the bonds among atoms in the layer LY. Alternatively, the beam 141 is configured to oxidize or nitridize the layer LY. Therefore, the layer LY becomes soft and is easy to be polished.

The platen 110 is configured and designed to secure the wafer W by a securing mechanism, such as a vacuum chuck or an electrostatic chuck (ESC). The CMP apparatus 100 further includes a first rotating device 160 electrically connected to the controller 150. The controller 150 controls the first rotating device 160 to rotate the platen 110 about a first axis Z1. In other words, the wafer W can be rotated about the first axis Z1.

The pad holder 120 includes a main body 122, a compressing device 124, a second rotating device 126, and a second moving mechanism 128. The controller 150 is electrically connected to the compressing device 124, the second rotating device 126, and the second moving mechanism 128. The polishing pad 130 can be fixed (e.g., adhered) to the bottom surface 123 of the main body 122. During the operation of the CMP apparatus 100, the compressing device 124 is configured to apply the downward force to press the main body 122 (and the polishing pad 130) downwardly and towards the wafer W. The second rotating device 126 is configured to rotate the main body 122 about a second axis Z2, in which the second axis Z2 and the first axis Z1 are substantially parallel with each other. In other words, the polishing pad 130 can be rotated about the second axis Z2. In this way, when the polishing pad 130 contacts with the wafer W under the downward force supplied from the compressing device 124, at least one of the rotation of the wafer W about the first axis Z1 and the rotation of the polishing pad 130 about the second axis Z2 will cause the wafer W and the polishing pad 130 to rub against each other. The controller 150 further controls the second moving mechanism 128 to move the position of the main body 122 along X, Y, and Z axes.

In some embodiments, the CMP apparatus 100 further includes a slurry introduction device 170 between the pad holder 120 and the beam device 140. The slurry introduction device 170 is configured to supply slurry S onto the polishing pad 130. The controller 150 is further electrically connected to the slurry introduction device 170 to control the supply of the slurry S from the slurry introduction device 170.

As shown in FIG. 1B, the platen 110 has a diameter D1, the wafer W has a diameter D2, the main body 122 of the pad holder 120 has a diameter D3, and the polishing pad 130 has a diameter D4. In some embodiments, the diameter D1 of the platen 110 is substantially equal to or greater than the diameter D2 of the wafer W. In some embodiments, the diameter D2 of the wafer W is greater than the diameter D3 of the main body 122 of the pad holder 120 and the diameter D4 of the polishing pad 130. In some embodiments, the diameter D3 of the main body 122 of the pad holder 120 is substantially equal to or greater than the diameter D4 of the polishing pad 130. In some embodiments, the ratio of the diameter D2 of the wafer W to the diameter D4 of the polishing pad 130 may be in a range from about 0.25 to about 4.

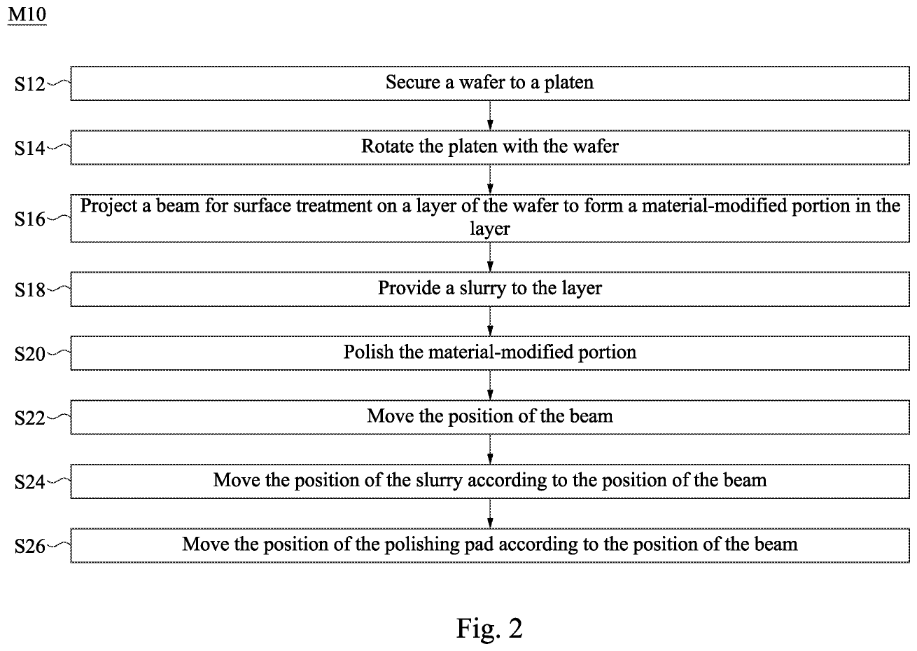

FIG. 2 is a flow chart of a method M10 of a polishing process according to some embodiments. The method M10 is merely an example, and is not intended to limit the present disclosure beyond what is explicitly recited in the claims. Additional operations can be provided before, during, and after the method M10, and some operations described can be replaced, eliminated, or moved around for additional embodiments of the process. For clarity and ease of explanation, some elements of the figures have been simplified. For illustration, the flow chart of FIG. 2 will be described along with the schematic views shown in FIGS. 1A-1B and FIGS. 3-9. The illustration is merely exemplary and is not intended to limit beyond what is specifically recited in the claims that follow.

Method M10 includes operation S12: a wafer is secured to the platen. For example, as shown in FIGS. 1A and 1B, the wafer W is placed on the platen 110, and a securing mechanism of the platen 110 is active to secure the wafer W on the top surface of the platen 110. In some embodiments, the securing mechanism of the platen 110 is a vacuum device, which provides suction forces in openings at the top surface of the platen 110, and the wafer W is fixed on the top surface of the platen 110 by the suction forces. The layer LY intended to be polished faces upward.

In some embodiments, the layer LY may be made of a suitable nitride (e.g., AlN, BN, or the like), a suitable metal oxide (e.g., Y₂O₂, YAG, Al₂O₂, BeO, or the like), a carbide (e.g., SiC, graphene, DLC, diamond, or the like), combinations thereof, or the like. In some embodiments, the layer LY is a heat dissipation layer (e.g., the heat dissipation layer 670 and/or 675 as shown in FIGS. 19-23).

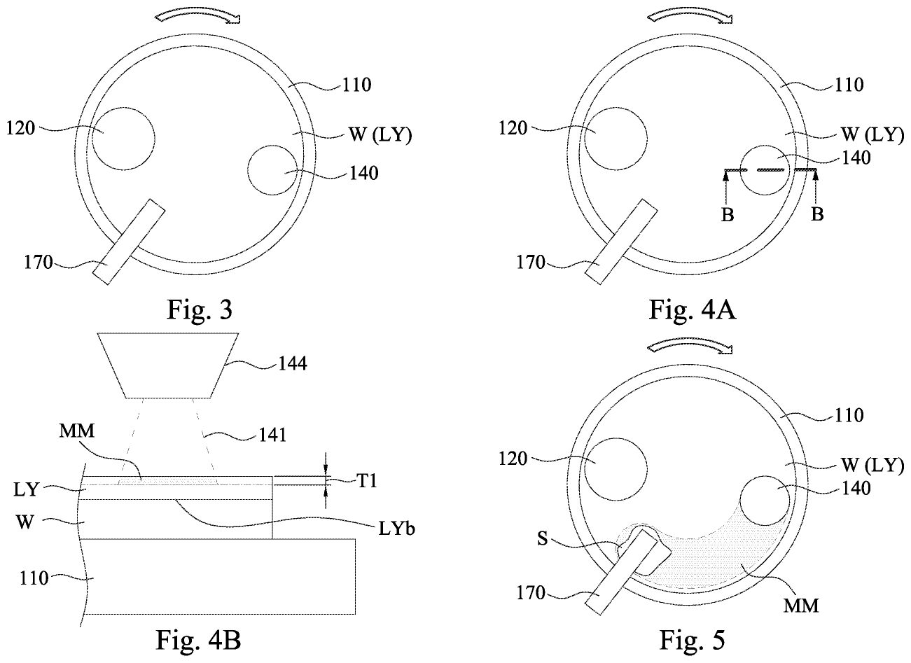

Method M10 includes operation 514: the platen is rotated with the wafer. For example, as shown in FIGS. 1B and 3, the controller 150 controls the first rotating device 160 to rotate the platen 110 and the wafer W about the first axis Z1. The platen 110 may be rotated clockwisely or counterclockwisely in a top view (see FIG. 3).

Method M10 includes operation S16: a beam for surface treatment is projected on a layer of the wafer to form a material-modified portion in the layer. As shown in FIGS. 1B, 4A, and 4B, where FIG. 4B is a cross-sectional view taken along line B-B in FIG. 4A, the controller 150 controls the beam device 140 to emit the beam 141 downwardly, such that the beam 141 is incident on the layer LY of the wafer W.

As mentioned above, the beam 141 is a laser beam or a plasma beam. The beam 141 is configured to damage or soften the layer LY to form a material-modified portion MM at a top of the layer, such that the layer LY is easy to be polished by the polishing pad 130. For example, the beam 141 breaks the bonds among the atoms of the layer LY. Alternatively, the beam 141 oxidizes or nitridizes the layer LY. As shown in FIG. 4B, the material-modified portion MM is spaced apart from a bottom surface LYb of the layer LY.

In some embodiments, the layer LY is a diamond layer, which includes C—C bonds therein. When the beam 141 is a laser beam, the beam 141 has a wavelength that is able to break at least one of the C—C bonds. For example, the laser beam has a wavelength shorter than about 400 nm. The laser beam may not have energy high enough to break the C—C bonds if the wavelength of the laser beam is longer than about 400 nm. Further, the power of the laser beam depends on the polishing thickness T1 of the layer LY. As shown in FIG. 4B, the power of the laser beam is strong enough to emit the beam 141 to the layer LY but not too strong in case that the beam 141 propagates deeper than the polishing thickness T1.

When the beam 141 is a plasma beam, the beam 141 may be an oxygen-containing plasma, e.g., O₂ plasma. When the oxygen-containing plasma is incident on the layer LY, the portion of the layer LY irradiated or illuminated by the oxygen-containing plasma is oxidized to be the material-modified portion MM, such that the material-modified portion MM is an oxide material. In some other embodiments, the beam 141 may be a nitrogen-containing plasma, e.g., N₂ plasma. When the oxygen-containing plasma is incident on the layer LY, the portion of the layer LY irradiated or illuminated by the oxygen-containing plasma is nitridized to be the material-modified portion MM, such that the material-modified portion MM is a nitride material. Further, the power of the plasma depends on the polishing thickness T1 of the layer LY. As shown in FIG. 4B, the power of the plasma is strong enough to emit the plasma beam to the layer LY but not too strong in case that the beam 141 propagates deeper than the polishing thickness T1. It is noted that the plasma beam is not limited to the oxygen-containing plasma and/or the nitrogen-containing plasma as mentioned above. In some other embodiments, the plasma beam includes any suitable plasma that can damage or soften the layer LY.

Method M10 includes operation S18: a slurry is provided to the layer. For example, in FIGS. 1B and 5, after the beam 141 is incident on the top surface of the layer LY, the material-modified portion MM is rotated toward a position beneath the slurry introduction device 170. The controller 150 controls the slurry introduction device 170 to provide the slurry S on the material-modified portion MM. In some embodiments, the slurry S includes any slurry known in the art, such as commercially available slurries for chemical mechanical polishing processes.

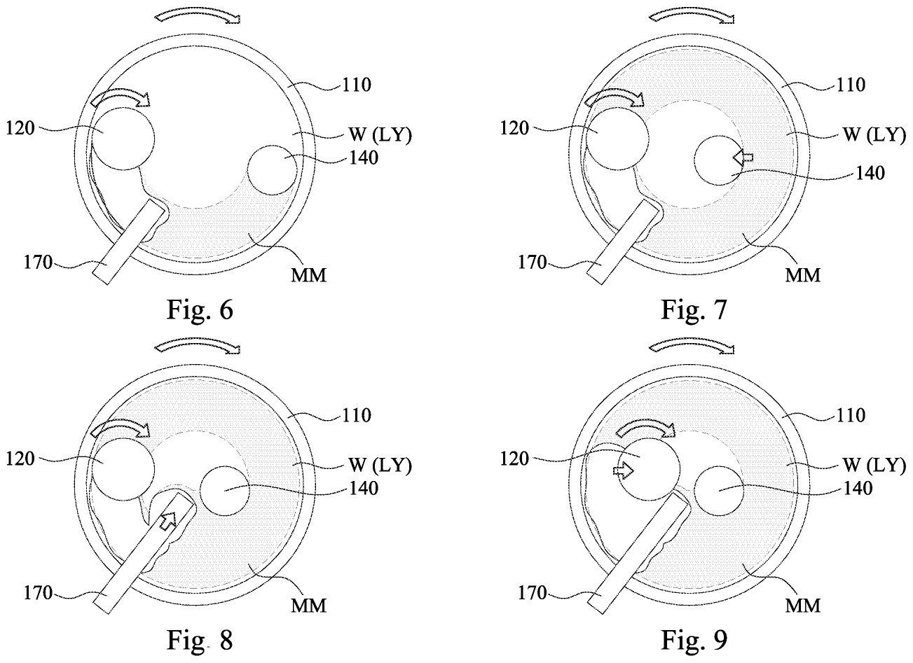

Method M10 includes operation S20: the material-modified portion is polished. For example, as shown in FIGS. 1B and 6, the material-modified portion MM is rotated toward a position beneath the pad holder 120 and the polishing pad 130. The controller 150 controls the second rotating device 126 to rotate the polishing pad 130 about the second axis Z2. The polishing pad 130 may be rotated clockwisely or counterclockwisely in a top view. The controller 150 then controls the compressing device 124 to press the polishing pad 130 toward the wafer W.

As mentioned above, since the material-modified portion MM has been irradiated or illuminated by the beam 141, the material-modified portion MM is softer than the other portions of the layer LY. Therefore, the polishing pad 130 is able to polish the material-modified portion MM effectively, and the polishing pad 130 is not damaged or consumed too much when the polishing pad 130 polishes the layer LY (if the layer LY is too hard such as the diamond). In some embodiments, the polishing pad 130 includes any polishing pad known in the art, such as commercially available polishing pads for chemical mechanical polishing processes.

Method M10 includes operation S22: the position of the beam is moved. As shown in FIGS. 1B and 7, in some embodiments, the controller 150 controls the first moving mechanism 146 to move the beam 141 relative to the wafer W. For example, as shown in FIGS. 4A and 7, the beam emitter 144 and/or the beam device 140 (so as the beam 141) is shifted from the edge of the wafer W toward the center of the wafer W. Therefore, the beam 141 can be incident on other portions of the layer LY. In some other embodiments, the beam 141 is shifted from the center of the wafer W toward the edge of the wafer W. The beam 141 is able to move in various paths on the wafer W, such that the entire of the top surface of the layer LY can be projected by the beam 141.

Method M10 includes operation S24: the position of the slurry is moved according to the position of the beam. As shown in FIGS. 1B and 8, in some embodiments, the controller 150 controls the slurry introduction device 170 to move the position of a nozzle of the slurry introduction device 170 according to the position of the beam 141. As such, the slurry S can be dispensed on the new formed material-modified portion MM.

Method M10 includes operation S26: the position of the polishing pad is moved according to the position of the beam. As shown in FIGS. 1B and 9, in some embodiments, the controller 150 controls the second moving mechanism 128 to move the position of the main body 122 as well as the polishing pad 130 according to the position of the beam 141. As such, the polishing pad 130 can polish the new formed material-modified portion MM.

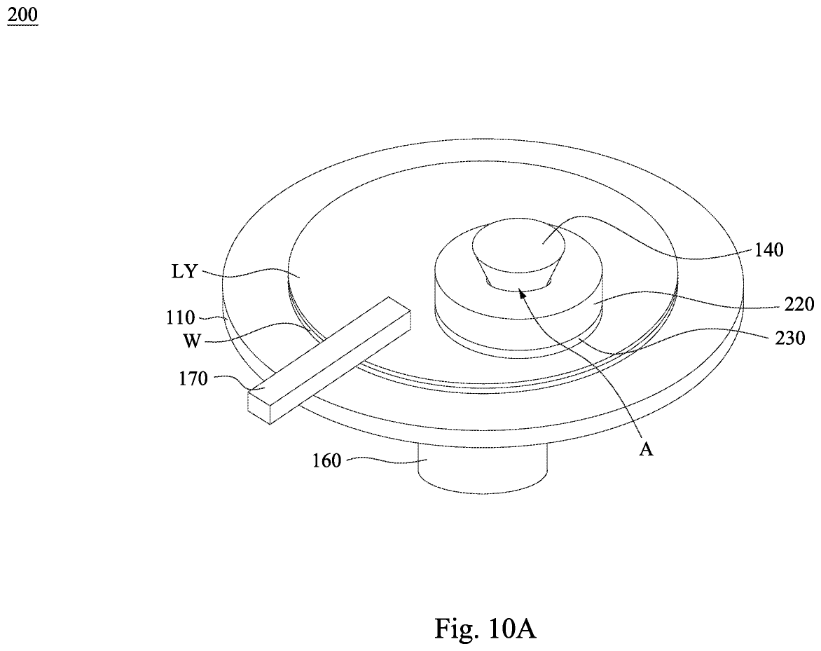

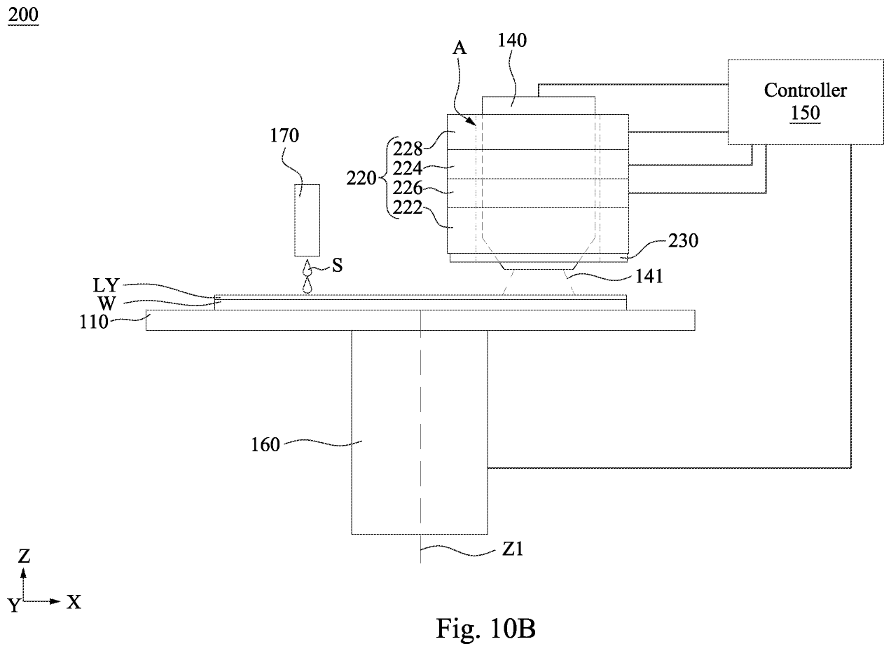

FIG. 10A is a schematic view of a CMP apparatus 200 in accordance with some embodiments, and FIG. 10B is a side view of the CMP apparatus 200 in FIG. 10A. The CMP apparatus 200 includes a platen 110, a pad holder 220, a polishing pad 230, a beam device 140, and a controller 150. The difference between the CMP apparatus 200 and the CMP apparatus 100 in FIGS. 1A and 1B pertains to the shapes of the pad holder 220 and the polishing pad 230 and the position of the beam device 140. In FIGS. 10A and 10B, at least the main body 222 of the pad holder 220 is ring-shaped. As such, the polishing pad 230 is ring-shaped. In some embodiments, the compressing device 224, the second rotating device 226, and the second moving mechanism 228 of the pad holder 220 are ring-shaped as well. The main body 222 (or the pad holder 220) defines an accumulation space A therein. In other words, the accumulation space A is surrounded by the main body 222. The beam device 140 is disposed in the accumulation space A, such that the beam device 140 is surrounded by the main body 222 of the pad holder 220. The platen 110 of the CMP apparatus 200 is similar to or the same as the platen 110 of the CMP apparatus 100 (see FIGS. 1A and 1B), the beam device 140 of the CMP apparatus 200 is similar to or the same as the beam device 140 of the CMP apparatus 100, and the controller 150 of the CMP apparatus 200 is similar to or the same as the controller 150 of the CMP apparatus 100. In addition, similar to the CMP apparatus 100, the CMP apparatus 200 further includes the first rotating device 160 and the slurry introduction device 170. Other relevant details of the CMP apparatus 200 are similar to or the same as the CMP apparatus 100, and, therefore, a description in this regard will not be repeated hereinafter.

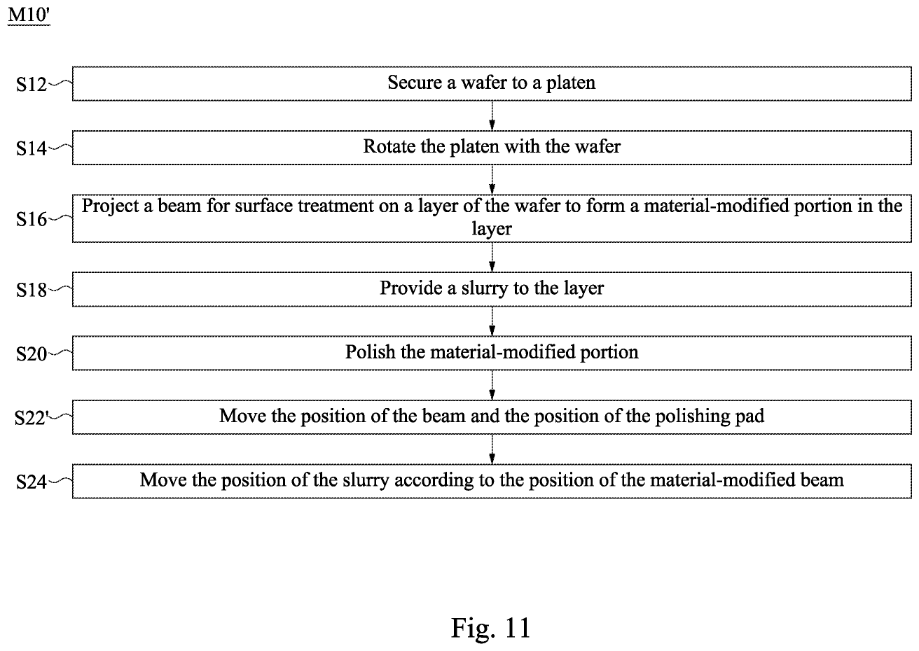

FIG. 11 is a flow chart of a method M10′ of a polishing process according to some embodiments. The method M10′ is similar to the method M10 of FIG. 2 except the operations S22 and S26. In the method M10′, the operations S22 and S26 of the method M10 are omitted. Instead, the method M10′ includes operation S22′: the position of the polishing pad and the position of the beam are moved. As shown in FIGS. 10A and 10B, since the beam device 140 is surrounded by the pad holder 220, the beam 141 moves along with the pad holder 220. Other relevant operation details of the method M10′ are similar to or the same as the method M10, and, therefore, a description in this regard will not be repeated hereinafter.

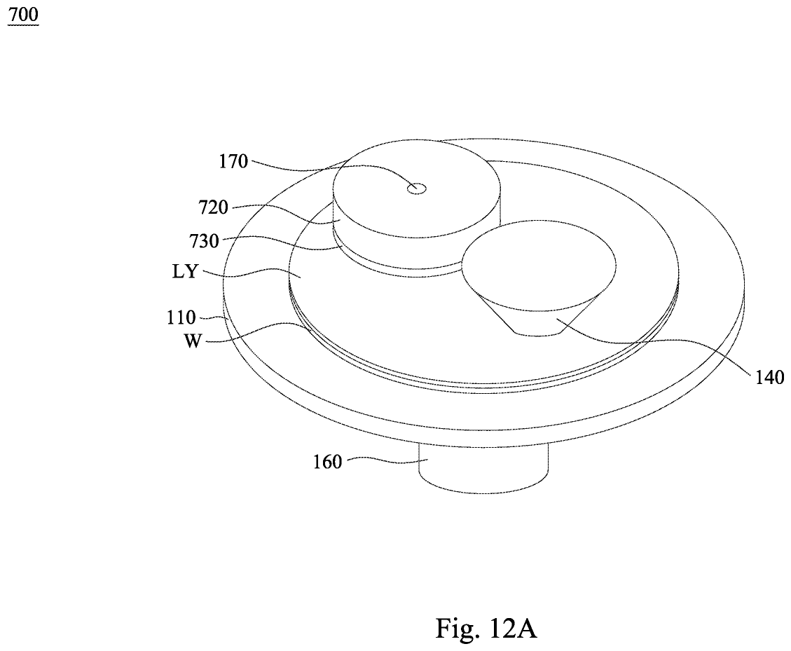

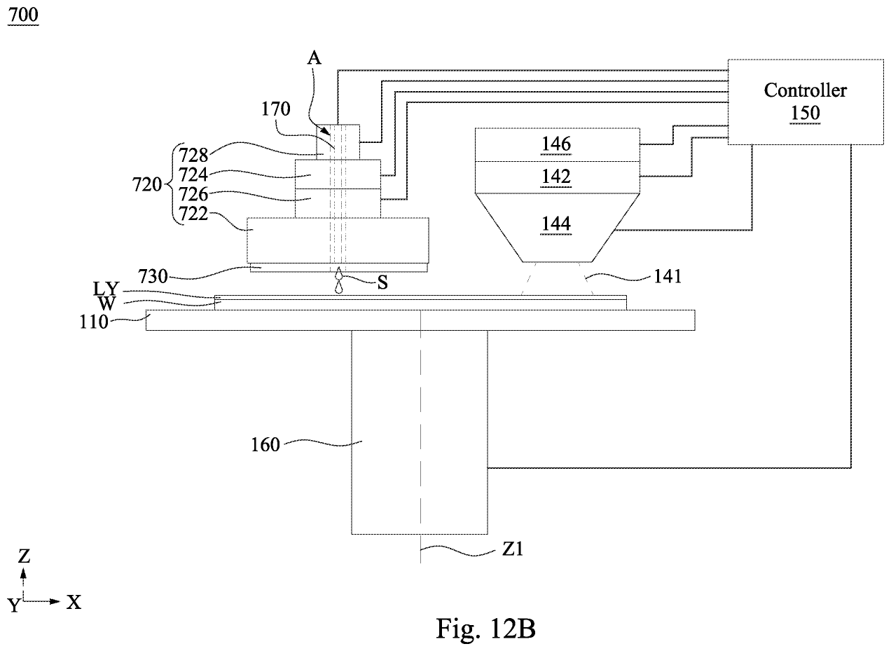

FIG. 12A is a schematic view of a CMP apparatus 700 in accordance with some embodiments, and FIG. 12B is a side view of the CMP apparatus 700 in FIG. 12A. The CMP apparatus 700 includes a platen 110, a pad holder 720, a polishing pad 730, a beam device 140, a controller 150, and a slurry introduction device 170. The difference between the CMP apparatus 700 and the CMP apparatus 100 in FIGS. 1A and 1B pertains to the shapes of the pad holder 720 and the polishing pad 730 and the position of the slurry introduction device 170. In FIGS. 12A and 12B, at least the main body 722 of the pad holder 720 is ring-shaped. As such, the polishing pad 730 is ring-shaped. In some embodiments, the compressing device 724, the second rotating device 726, and the second moving mechanism 728 of the pad holder 720 are ring-shaped as well. The main body 722 (or the pad holder 720) defines an accumulation space A therein. In other words, the accumulation space A is surrounded by the main body 722. The slurry introduction device 170 is disposed in the accumulation space A and fixed on the pad holder 720, such that the slurry introduction device 170 is surrounded by the main body 722 of the pad holder 720. The platen 110 of the CMP apparatus 700 is similar to or the same as the platen 110 of the CMP apparatus 100 (see FIGS. 1A and 1B), the beam device 140 of the CMP apparatus 700 is similar to or the same as the beam device 140 of the CMP apparatus 100, the controller 150 of the CMP apparatus 700 is similar to or the same as the controller 150 of the CMP apparatus 100, and the slurry introduction device 170 of the CMP apparatus 700 is similar to or the same as the slurry introduction device 170 of the CMP apparatus 100. In addition, similar to the CMP apparatus 100, the CMP apparatus 700 further includes the first rotating device 160. Other relevant details of the CMP apparatus 700 are similar to or the same as the CMP apparatus 100, and, therefore, a description in this regard will not be repeated hereinafter.

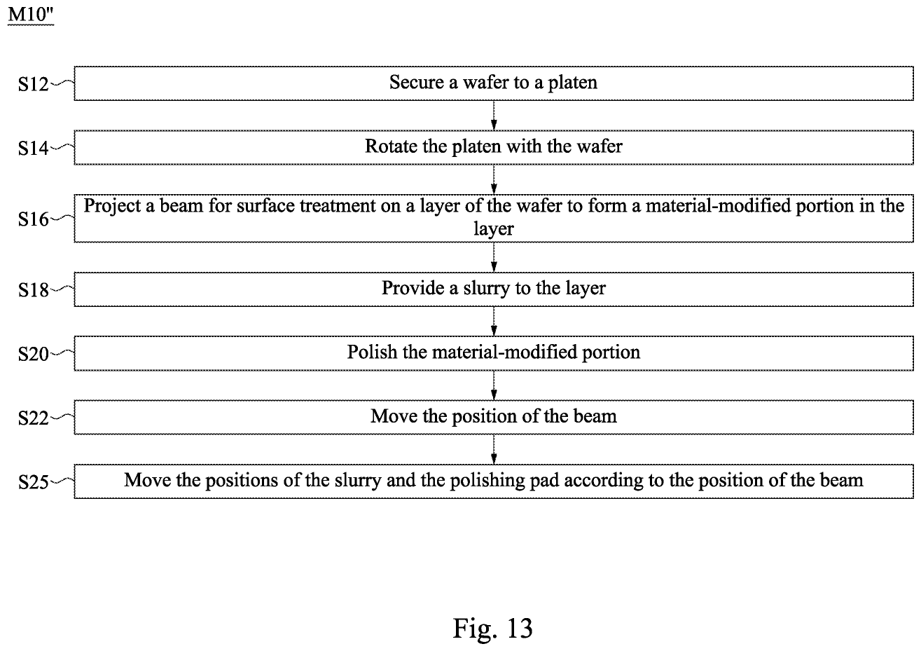

FIG. 13 is a flow chart of a method M10″ of a polishing process according to some embodiments. The method M10″ is similar to the method M10 of FIG. 2 except the operations S24 and S26. In the method M10″, the operations S24 and S26 of the method M10 are omitted. Instead, the method M10″ includes operation S25: the positions of the slurry and the polishing pad are moved. As shown in FIGS. 12A and 12B, since the slurry introduction device 170 is surrounded by the pad holder 720, the slurry introduction device 170 moves along with the pad holder 720. Other relevant operation details of the method M10″ are similar to or the same as the method M10, and, therefore, a description in this regard will not be repeated hereinafter.

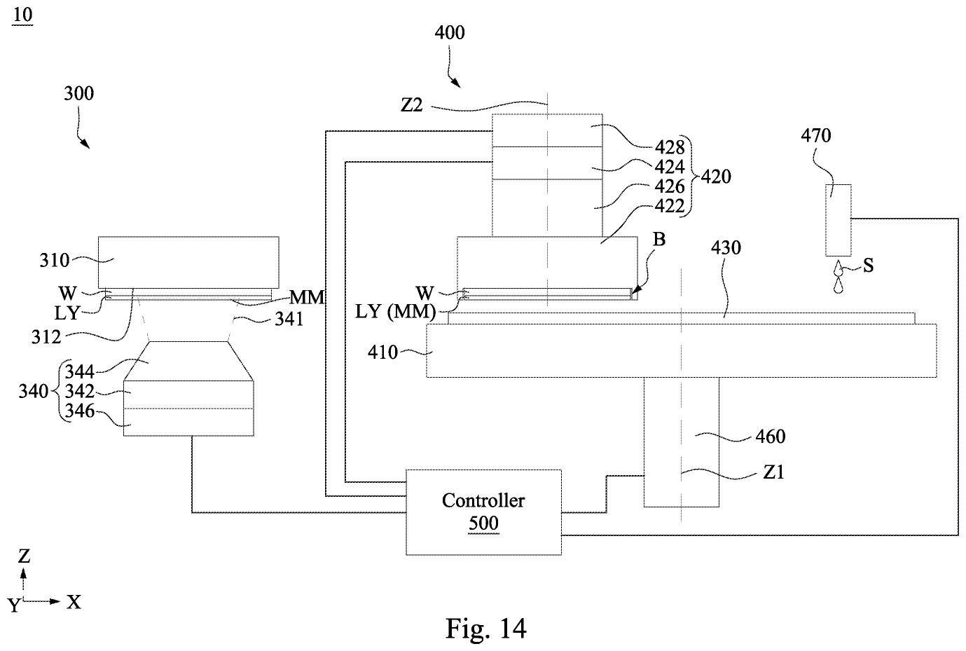

FIG. 14 is a side view of a CMP system 10 in accordance with some embodiments. The CMP system 10 includes a surface treatment device 300, a CMP apparatus 400, and a controller 500. The surface treatment device 300 includes a chuck 310 and a beam device 340. The chuck 310 is disposed over the beam device 340. The chuck 310 is configured and designed to secure the wafer W by a securing mechanism, such as a vacuum chuck or an electrostatic chuck (ESC). In some embodiments, the wafer W including the layer LY is placed on the bottom surface 312 of the chuck 310, such that the layer LY faces the beam device 340. The beam device 340 has a similar configuration to the beam device 140 (see FIG. 1B). That is, the beam device 340 includes a beam source 342, a beam emitter 344, and a first moving mechanism 346. The beam source 342 in FIG. 14 is similar to or the same as the beam source 142 in FIG. 1B, the beam emitter 344 in FIG. 14 is similar to or the same as the beam emitter 144 in FIG. 1B, and the first moving mechanism 346 in FIG. 14 is similar to or the same as the first moving mechanism 346 in FIG. 1B. The controller 500 is electrically connected to the beam device 340.

The CMP apparatus 400 includes a platen 410, a polishing head 420, a polishing pad 430, a first rotating device 460, and slurry introduction device 470. The polishing pad 430 can be adhered to the top surface of the platen 110. The rotating device 460 is similar to the first rotating device 160 in FIG. 1B and configured to rotate the platen 110 and the polishing pad 430 about the first axis Z1. The polishing head 420 is disposed over the platen 110 and configured to secure the wafer W during the polishing process. The polishing head 420 includes a main body 422, a compressing device 424, a second rotating device 426, and a second moving mechanism 428. The bottom of the main body 422 has an accumulation space B for accumulating and securing the wafer W.

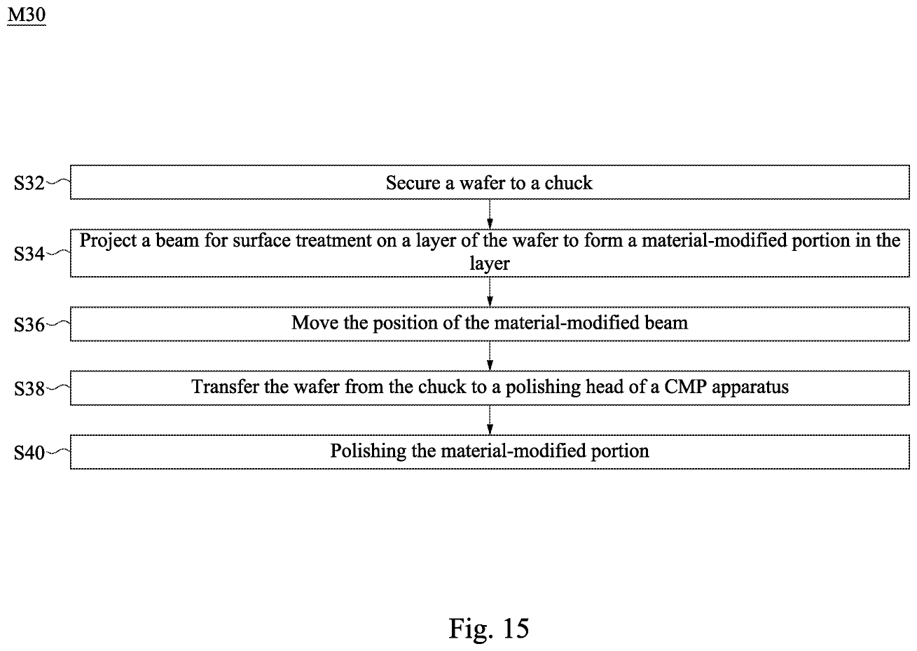

FIG. 15 is a flow chart of a method M30 of a polishing process according to some embodiments. The method M30 is merely an example, and is not intended to limit the present disclosure beyond what is explicitly recited in the claims. Additional operations can be provided before, during, and after the method M30, and some operations described can be replaced, eliminated, or moved around for additional embodiments of the process. For clarity and ease of explanation, some elements of the figures have been simplified. For illustration, the flow chart of FIG. 15 will be described along with the schematic views shown in FIG. 14. The illustration is merely exemplary and is not intended to limit beyond what is specifically recited in the claims that follow.

Method M30 includes operation S32: a wafer is secured to a chuck. For example, as shown in FIG. 14, the wafer W is placed on a bottom surface of the chuck 310, and a securing mechanism of the chuck 310 is active to secure the wafer W on the bottom surface of the chuck 310. In some embodiments, the securing mechanism of the chuck 310 is a vacuum device, which provides suction forces in openings at the bottom surface of the chuck 310, and the wafer W is fixed to the bottom surface of the chuck 310 by the suction forces. The layer LY intended to be polished faces downward.

Method M30 includes operation S34: a beam for surface treatment is projected on a layer of the wafer to form a material-modified portion in the layer. As shown in FIG. 14, the controller 500 controls the beam device 340 to emit the beam 341 upward, such that the beam 341 is incident on the layer LY of the wafer W and form the material-modified portion MM in the layer LY. The process details of the operation S34 is similar to the operation S16 of method M10, and, therefore, a description in this regard will not be repeated hereinafter.

Method M30 includes operation S36: the position of the beam is moved. As shown in FIG. 14, in some embodiments, the controller 500 controls the first moving mechanism 346 to move the beam 341 relative to the wafer W. For example, the beam emitter 344 and/or the beam device 340 (so as the beam 341) is shifted along X and Y axes. Therefore, the beam 341 can be incident on other portions of the layer LY. The beam 341 is able to move in various paths on the wafer W, such that the entirety of the top surface of the layer LY can be projected by the beam 341.

Method M30 includes operation S38: the wafer is transferred from the chuck to a polishing head of a CMP apparatus. As shown in FIG. 14, in some embodiments, after the material-modified portion MM is formed in the layer LY, the wafer W is removed from the chuck 310. Thereafter, the wafer W is transferred to the CMP apparatus 400 and then is secured (or clamped) by the polishing head 420, and the layer LY including the material-modified portion MM faces downward.

Method M30 includes operation S40: the material-modified portion is polished. For example, as shown in FIG. 14, the polishing pad 430 is adhered to the top surface of the platen 410, and the controller 500 controls the first rotating device 460 to rotate the platen 410 and the polishing pad 430 about the first axis Z1. The platen 410 may be rotated clockwisely or counterclockwisely in a top view.

Subsequently, the controller 500 controls the slurry introduction device 470 to provide the slurry S on the polishing pad 430. In some embodiments, the slurry S includes any slurry known in the art, such as commercially available slurries for chemical mechanical polishing processes.

Next, the controller 500 controls the second rotating device 426 to rotate the main body 422 and the wafer W about the second axis Z2. The wafer W may be rotated clockwisely or counterclockwisely in a top view. The controller 500 then controls the compressing device 424 to press the wafer W toward the polishing pad 430. In this way, when the wafer W contacts with the polishing pad 430 under the downward force supplied from the compressing device 424, at least one of the rotation of the wafer W about the second axis Z2 and the rotation of the polishing pad 430 about the first axis Z2 will cause the wafer W and the polishing pad 430 to rub against each other. In some embodiments, the controller 500 further controls the second moving mechanism 428 to move the position of the main body 422 along X, Y, and Z axes.

FIGS. 16-19 illustrate cross-sectional views of intermediate stages in the formation of a semiconductor device 600 in accordance with some embodiments of the present disclosure. Throughout the various views and illustrative embodiments, like reference numbers are used to designate like elements. It is understood that additional operations can be provided before, during, and after the processes shown by FIGS. 16-19, and some of the operations described below can be replaced or eliminated, for additional embodiments of the method. The order of the operations/processes may be interchangeable.

Reference is made to FIG. 16. A device layer 620 is formed over a substrate 610. The substrate 610 is made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. Further, the substrate 610 may include an epitaxial layer (epi-layer), which may be strained for performance enhancement, and/or may include a silicon-on-insulator (SOI) structure.

In some embodiments, the device layer 620 includes a plurality of passive components, such as resistors, capacitors, and inductors, and/or active components, such as p-type FETs (PFETs), n-type FETs (NFETs), multi-gate FETs, MOSFETs, complementary metal-oxide semiconductor (CMOS) transistors, bipolar transistors, high voltage transistors, high frequency transistors, other memory cells, and combinations thereof. In some embodiments, the transistors in the device layer may be planar FETs, FinFETs, GAA FETs, CFET, or combinations thereof.

A front-side interconnect structure 630 is formed on the device layer 620. The front-side interconnect structure 630 may be referred to as a front-side interconnect structure because it is formed on a front-side of the transistor structures (e.g., a side of the transistor structures on which active devices are formed) in the device layer 620.

The front-side interconnect structure 630 may include one or more layers of conductive features 632 formed in one or more stacked dielectric layers 634. Each of the stacked dielectric layers 634 may include a dielectric material, such as a low-k dielectric material, an extra low-k (ELK) dielectric material, or the like. The conductive features 632 may include conductive lines and conductive vias interconnecting the layers of conductive lines.

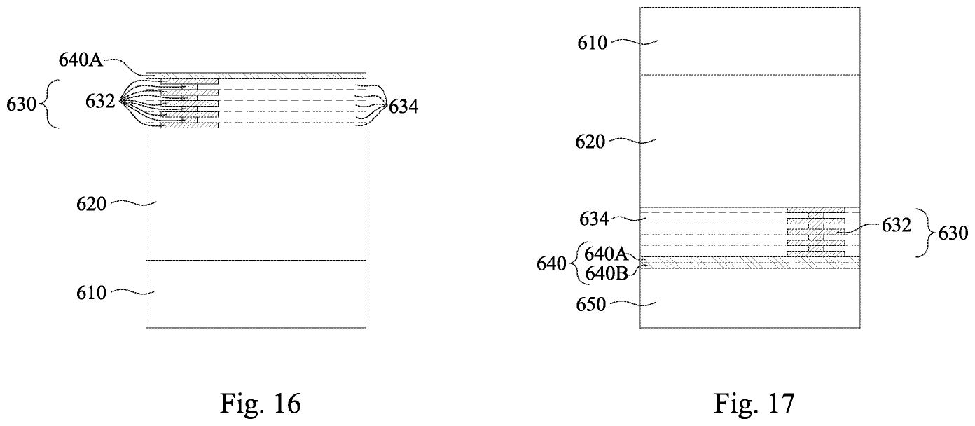

Subsequently, a first bonding layer 640A may be deposited over the front-side interconnect structure 630. The first bonding layer 640A may facilitate the bonding of a carrier substrate 650 in subsequent processes (see FIG. 17). The first bonding layer 640A may include an insulating material that is suitable for a subsequent dielectric-to-dielectric bonding process. Example materials for the first bonding layer 640A include silicon oxide (e.g., SiO₂), silicon nitride, silicon oxynitride, silicon carbonitride, silicon oxycarbonitride, or the like.

Reference is made to FIG. 17. A carrier substrate 650 is bonded to a top surface of the front-side interconnect structure 630 by the first bonding layer 640A and a second bonding layer 640B. After bonding, the first bonding layer 640A and the second bonding layer 640B may be collectively referred to as a bonding layer 640. It should be appreciated that the bonding layer 640 may include an internal interface where the first bonding layer 640A and the second bonding layer 640B meet.

The carrier substrate 650 may be a glass carrier substrate, a ceramic carrier substrate, a wafer (e.g., a silicon wafer), or the like. The carrier substrate 650 may provide structural support during subsequent processing steps and in the completed device. The second bonding layer 640B may be deposited on the carrier substrate 650 by any suitable process, such as PVD, CVD, ALD, or the like. The second bonding layer 640B may include an insulating material that is suitable for a dielectric-to-dielectric bonding process. Example materials for the second bonding layer 640B include silicon oxide (e.g., SiO₂), silicon nitride, silicon oxynitride, silicon carbonitride, silicon oxycarbonitride, or the like. The second bonding layer 640B may have a same or different thickness than the first bonding layer 640A.

After the carrier substrate 650 is bonded to the front-side interconnect structure 630, the device may be flipped such that a backside of the device layer 620 faces upwards. The backside of the device layer 620 may refer to a side opposite to the front-side of the device layer 620 on which the active devices are formed.

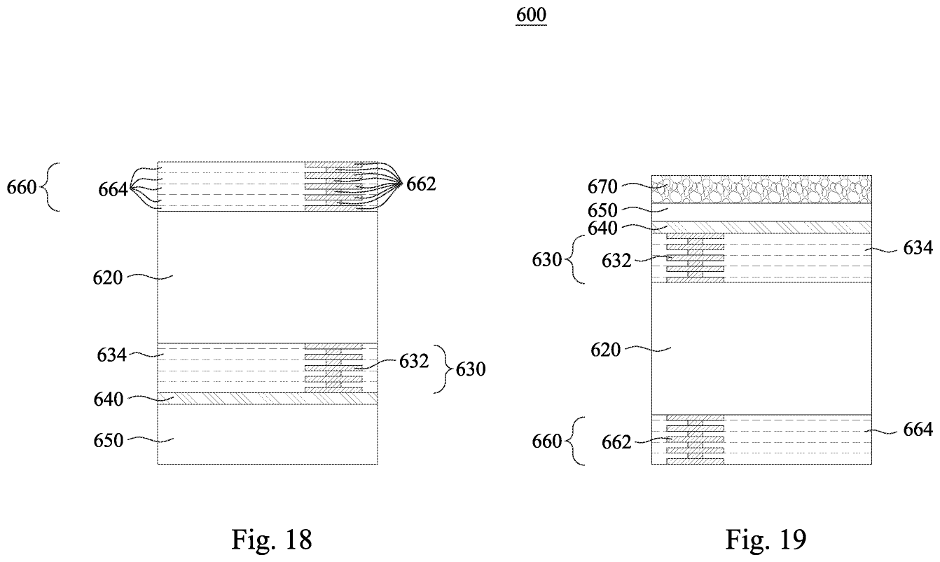

Reference is made to FIG. 18. The substrate 610 (see FIG. 17) may be removed to expose the backside of the device layer 620. Subsequently, a backside interconnect structure 660 is formed over the backside of the device layer 620. The backside interconnect structure 660 may be referred to as a backside interconnect structure because it is formed on a backside of the device layer in which the device layer 620 are disposed. The backside interconnect structure 660 may include materials and be formed using processes the same as or similar to those used for the front-side interconnect structure 630. In particular, the backside interconnect structure 660 may include stacked layers of conductive features 662 formed in dielectric layers 664. The conductive features 662 may include routing lines (e.g., for routing to and from subsequently formed contact pads and external connectors). The conductive features 662 may further be patterned to include one or more embedded passive devices such as, resistors, capacitors, inductors, or the like. The dielectric layers 664 may be formed of similar materials using similar processes as the dielectric layers 634, and the conductive features 662 may be formed of similar materials using similar processes as the conductive features 632.

Reference is made to FIG. 19. An orientation of the device is flipped such that the carrier substrate 650 is disposed over the front-side interconnect structure 630, the device layer 620, and the backside interconnect structure 660. Subsequently, a thinning process (e.g., a CMP process, a mechanical grinding process, an etch back process, combinations thereof, or the like) may be applied to the carrier substrate 650 such that an overall thickness of the carrier substrate 650 is reduced.

Subsequently, a heat dissipation layer 670 is deposited on a lateral surface of the carrier substrate 650 that is opposite to the front-side interconnect structure 630, the device layer 620, and the backside interconnect structure 660. The heat dissipation layer 670 is made of a high-kappa material having a thermal conductivity greater than 10 W/m·K. It has been observed that when the heat dissipation layer 670 has a thermal conductivity in the above range, thermal dissipation in the completed integrated circuit die is sufficiently improved. For example, the heat dissipation layer 670 may be made of a suitable nitride (e.g., AlN, BN, or the like), a suitable metal oxide (e.g., Y₂O₂, YAG, Al₂O₂, BeO, or the like), a carbide (e.g., SiC, graphene, DLC, diamond, or the like), combinations thereof, or the like. In some specific embodiments, the high-kappa material is DLC, and junction to ambient thermal resistance (θJA) of the integrated circuit die can be improved by up to 1.33° C./W. In some embodiments, the heat dissipation layer 670 has a thermal conductivity in a range of 10 W/m·K to 1500 W/m·K to achieve the above benefits, such as in a range of 50 W/m·K to 1500 W/m·K, 100 W/m·K to 1500 W/m·K, 300 W/m·K to 1500 W/m·K, 700 W/m·K to 1500 W/m·K, 1000 W/m·K to 1500 W/m·K, or the like. The heat dissipation layer 670 may have a crystalline (e.g., single crystal or poly crystal) structure or an amorphous structure. In embodiments where the heat dissipation layer 670 has a crystalline structure, its crystal lattice may be hexagonal, tetragonal, orthorhombic, monoclinic, triclinic, combinations thereof, or the like.

In some embodiments, after the deposition of the heat dissipation layer 670 is performed, a planarization (or polishing) process is performed to the heat dissipation layer 670 to thin the heat dissipation layer 670 to a predetermined thickness. The planarization (or polishing) process may be performed with the methods M10, M10′, M10″, and/or M30 by using the CMP apparatus 100, 200 and/or 700 or the CMP system 10 mentioned above.

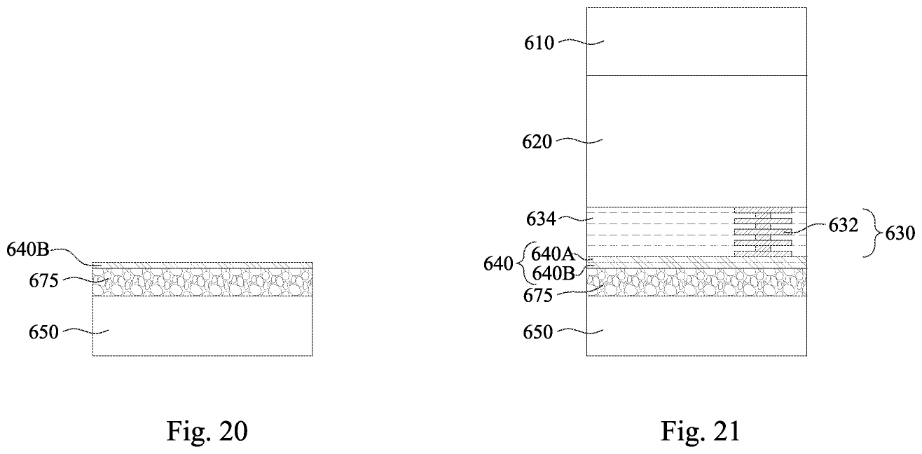

FIGS. 20-23 illustrate cross-sectional views of intermediate stages in the formation of a semiconductor device 600′ in accordance with some embodiments of the present disclosure. Throughout the various views and illustrative embodiments, like reference numbers are used to designate like elements. It is understood that additional operations can be provided before, during, and after the processes shown by FIGS. 20-23, and some of the operations described below can be replaced or eliminated, for additional embodiments of the method. The order of the operations/processes may be interchangeable.

Reference is made to FIG. 20. A heat dissipation layer 675 is deposited on the carrier substrate 650. The heat dissipation layer 675 may be made of a like material using like processes as described above with respect to the heat dissipation layer 670. In some embodiments, after the deposition of the heat dissipation layer 675 is performed, a planarization (or polishing) process is performed to the heat dissipation layer 675 to thin the heat dissipation layer 675 to a predetermined thickness. The planarization (or polishing) process may be performed with the methods M10, M10′, M10″, and/or M30 by using the CMP apparatus 100, 200 and/or 700 or the CMP system 10 as mentioned above. After that, the second bonding layer 640B is deposited on the heat dissipation layer 675.

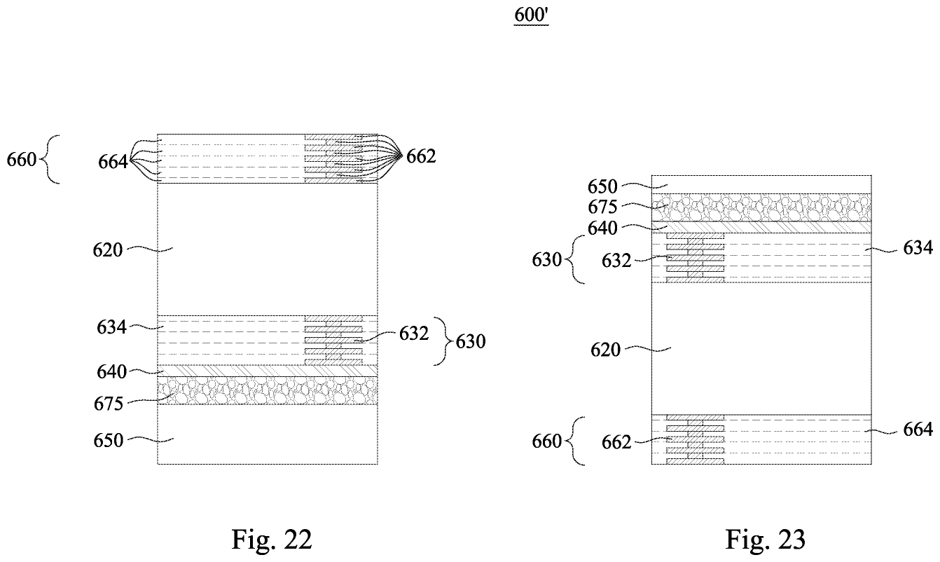

Reference is made to FIG. 21. The carrier substrate 650 having the heat dissipation layer 675 deposited thereon is bonded to the front-side interconnect structure 630 of the structure of FIG. 16. Thereafter, as shown in FIG. 22, the structure undergoes the process similar to FIG. 17 to form the backside interconnect structure 660. Next, an orientation of the device is flipped as shown in FIG. 23, and the carrier substrate 650 is thinned to form the semiconductor device 600′.

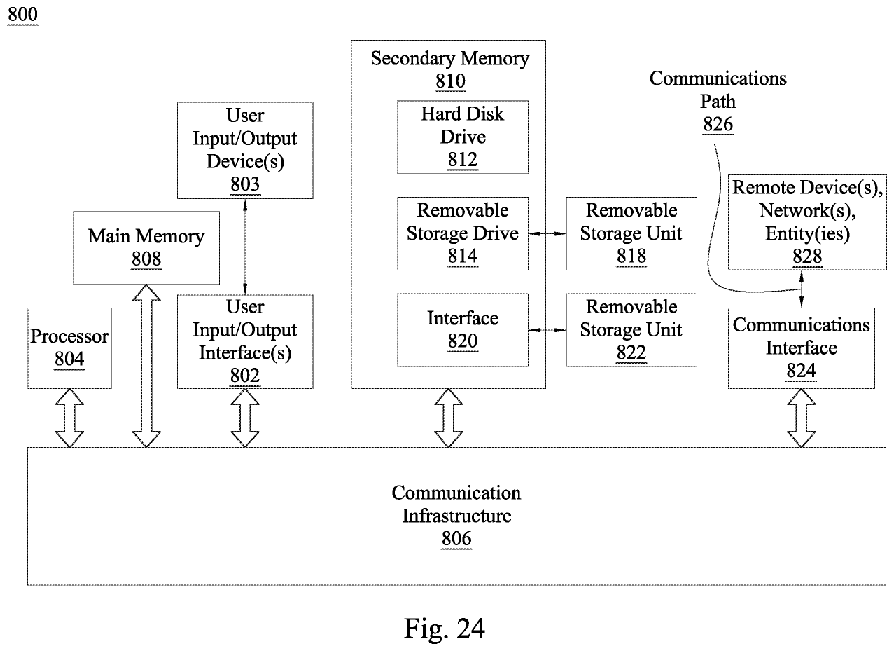

FIG. 24 a schematic diagram illustrating a computer system 800 in accordance with some embodiments of the present disclosure. In some embodiments, at least one of the controllers 150 and 500 may be also known as a computer system 800. As shown in FIG. 24, an illustration of an exemplary computer system 800 in which various embodiments of the present disclosure can be implemented, according to some embodiments. The computer system 800 may be used to control various components in the CMP apparatus 100, 200, 700, and/or the CMP system 10. The computer system 800 may be any well-known computer capable of performing functions and operations described in the present disclosure. For example, and without limitation, the computer system 800 may be capable of processing and transmitting signals. The computer system 800 may be used, for example, to execute one or more functions of the CMP apparatus 100, 200, 700, and/or the CMP system 10, which describes example operations of communications amongst different components therein.

The computer system 800 may include one or more processors (also called central processing units, or CPUs), such as a processor 804. The processor 804 is connected to a communication infrastructure or bus 806. The computer system 800 also includes input/output device(s) 803, such as monitors, keyboards, and pointing devices, that may communicate with communication infrastructure or bus 806 through input/output interface(s) 802. The computer system 800 may receive instructions to implement functions and operations described herein, e.g., functions of the CMP apparatus 100, 200, 700, and/or the CMP system 10 and methods M10, M10′, M10″, and M30, via the input/output device(s) 803. The computer system 800 also includes a main or primary memory 808, such as random access memory (RAM). The main memory 808 may include one or more levels of cache. The main memory 808 has stored therein control logic (e.g., computer software) and/or data. In some embodiments, the control logic (e.g., computer software) and/or data may include one or more of the functions described with respect to the CMP apparatus 100, 200, 700, and/or the CMP system 10.

The computer system 800 may also include one or more secondary storage devices or memory 810. The secondary memory 810 may include, for example, a hard disk drive 812 and/or a removable storage device or drive 814. Removable storage drive 814 can be a floppy disk drive, a magnetic tape drive, a compact disk drive, an optical storage device, tape backup device, and/or any other storage device/drive.

The removable storage drive 814 may interact with a removable storage unit 818. The removable storage unit 818 includes a computer usable or readable storage device having stored thereon computer software (control logic) and/or data. The removable storage unit 818 may be a floppy disk, magnetic tape, compact disk, DVD, optical storage disk, and/any other computer data storage device. The removable storage drive 814 reads from and/or writes to removable storage unit 818 in a well-known manner.

In some embodiments, the secondary memory 810 may include other means, instrumentalities or other approaches for allowing computer programs and/or other instructions and/or data to be accessed by the computer system 800. Such means, instrumentalities or other approaches can include, for example, a removable storage unit 822 and an interface 820. Examples of the removable storage unit 822 and the interface 820 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, the secondary memory 810, the removable storage unit 818, and/or the removable storage unit 822 may include one or more of the functions described with respect to the CMP apparatus 100, 200, 700, and/or the CMP system 10.

The computer system 800 may further include a communication or network interface 824. The communication interface 824 enables the computer system 800 to communicate and interact with any combination of remote devices, remote networks, remote entities, etc. (individually and collectively referenced by reference number 828). For example, the communication interface 824 may allow the computer system 800 to communicate with the remote devices 828 over the communications path 826, which may be wired and/or wireless, and which may include any combination of LANs, WANs, the Internet, etc. Control logic and/or data may be transmitted to and from the computer system 800 via the communication path 826.

The functions and/or operations in the preceding embodiments may be implemented in a wide variety of configurations and architectures. Therefore, some or all of the operations in the preceding embodiments, e.g., functions of the CMP apparatus 100, 200, 700, and/or the CMP system 10 and methods M10, M10′, M10″, and M30, may be performed in hardware, in software or both. In some embodiments, a tangible apparatus or article of manufacture including a tangible computer useable or readable medium having control logic (software) stored thereon is also referred to herein as a computer program product or program storage device. This includes, but is not limited to, the computer system 800, the main memory 808, the secondary memory 810, and the removable storage units 818 and 822, as well as tangible articles of manufacture embodying any combination of the foregoing. Such control logic, when executed by one or more data processing devices (such as the computer system 800), causes such data processing devices to operate as described in the present disclosure. In some embodiments, the computer system 800 includes hardware/equipment for the manufacturing of photomasks and circuit fabrication. For example, the hardware/equipment may be connected to or be part of the element 828 (remote device(s), network(s), entity(ies)) of the computer system 800.

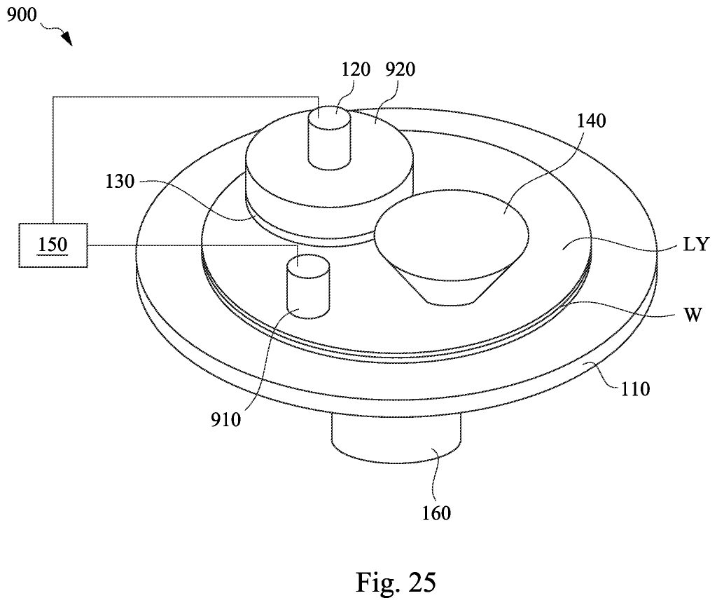

FIG. 25 is a schematic view of a CMP apparatus 900 in accordance with some embodiments. The CMP apparatus 900 includes a platen 110, a pad holder 120, a polishing pad 130, a beam device 140, a first rotating device 160, and a controller 150, in which the CMP apparatus 900 is configured to perform a CMP process on a layer LY over a wafer W. Details of the above elements have been discussed above, and thus relevant descriptions will not be repeated for brevity. In some embodiments, the pad holder 120 and the polishing pad 130 may also be the pad holder 720 and the polishing pad 730 as described in FIG. 12A. In some embodiments, the computer system 800 as discussed in FIG. 25 may be used to control various components in the CMP apparatus 900 as described herein.

The CMP apparatus 900 further includes a CMP endpoint detector 910 and a CMP endpoint detector 920 separated from each other. The CMP endpoint detectors 910 and 920 are configured to detect surface roughness and/or thickness of a target layer during performing a CMP process. In some embodiments, the target layer can be the layer LY, and can also be any layer in FIGS. 17-23 that undergoes a CMP process. As shown in FIG. 25, the CMP endpoint detectors 910 and 920 are electrically connected to and are controlled by the controller 150. The CMP endpoint detector 910 is separated from the pad holder 120 and the polishing pad 130. On the other hand, the CMP endpoint detector 920 is integrated with the pad holder 120 and the polishing pad 130. For example, the pad holder 120 and the polishing pad 130 may include a space for accommodating the CMP endpoint detector 920. In some embodiments, the CMP endpoint detector 920 and the beam device 140 (see FIG. 10B) can be integrated with the pad holder 120. In some embodiments, the CMP endpoint detector 920 and the slurry introduction device 170 (see FIG. 12B) can be integrated with the pad holder 120.

In some embodiments, the controller 150 may control the CMP endpoint detectors 910 and 920 to detect surface roughness and/or thickness of a target layer during the CMP process. When the surface roughness and/or the thickness of the target layer reach a predetermined value (e.g., a desired surface roughness and/or a desired thickness), the controller 150 may stop the CMP process. For example, the CMP process may be stopped by halting rotating the platen 110 and the polishing pad 130, or by separating the polishing pad 130 from the target layer.

As mentioned above, each of the CMP endpoint detectors 910 and 920 may be configured to detect surface roughness and/or thickness of a target layer. In some embodiments where CMP endpoint detectors 910 and 920 are a surface roughness detector, the surface roughness detector may measure the surface roughness of a target layer using suitable techniques, such as dark field inspection (by light scattering), torque signal (by fraction), surface probing (by directly measuring surface roughness), or other suitable methods. In some embodiments where CMP endpoint detectors 910 and 920 are a thickness detector, the thickness detector may measure the thickness of a target layer using suitable techniques, such as spectroscopic ellipsometry, spectroscopic reflectometry, white light interferometry, or other suitable methods.

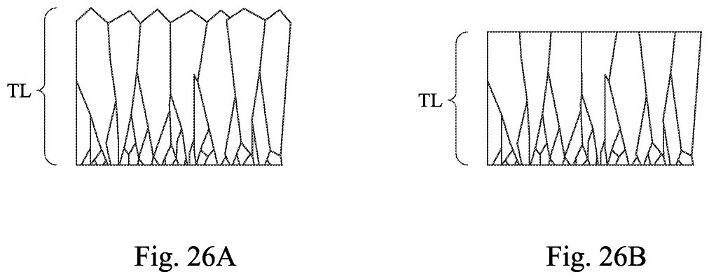

FIGS. 26A and 26B illustrate cross-sectional views of intermediate stages in the formation of a semiconductor device in accordance with some embodiments of the present disclosure. FIGS. 26A and 26B illustrate a method by performing a CMP process on a target layer TL, in which FIG. 26A is a cross-sectional view of the target layer TL prior to undergo a CMP process, and FIG. 26B is cross-sectional view of the target layer TL after undergo a CMP process.

In some embodiments, the target layer TL can be the layer LY of FIG. 25, and can also be any layer in FIGS. 17-23 that undergoes a CMP process. In some embodiments, the target layer TL may be a high-kappa material having a thermal conductivity greater than 10 W/m·K, such as a nitride (e.g., AlN, BN, or the like), a metal oxide (e.g., Y₂O₂, YAG, Al₂O₂, BeO, or the like), a carbide (e.g., SiC, graphene, DLC, diamond, or the like), combinations thereof, or the like.

Reference is made to FIG. 26A, prior to performing a CMP process, an endpoint detection method may be performed to detect an initial surface roughness and/or initial thickness of the target layer TL. In some embodiments, the initial surface roughness and/or the thickness of the target layer TL may be detected prior to performing the surface treatment (using the beam device 140) as described above.

Reference is made to FIG. 26B, the CMP process is performed on the target layer TL, so as to reduce the surface roughness and the thickness of the target layer TL. The endpoint detection method further includes detecting the surface roughness and/or the thickness of the polished target layer TL. In some embodiments, the surface roughness and/or the thickness of the polished target layer TL may be detected during performing the CMP process. Once the surface roughness and/or the thickness of the polished target layer TL reach a pre-determined condition, the CMP process is stopped. However, when the detected surface roughness and/or the detected thickness of the polished target layer TL do not reach the pre-determined condition, the CMP process may be continued until the surface roughness and/or the thickness of the polished target layer TL reach the pre-determined condition. In some embodiments, the “pre-determined condition” may include the surface roughness (or the thickness) of the polished target layer TL is less than a threshold value. In other embodiments, the “pre-determined condition” may include the difference between the initial surface roughness (or the initial thickness) of the target layer TL and the surface roughness (or the thickness) of the polished target layer TL is less than a threshold value.

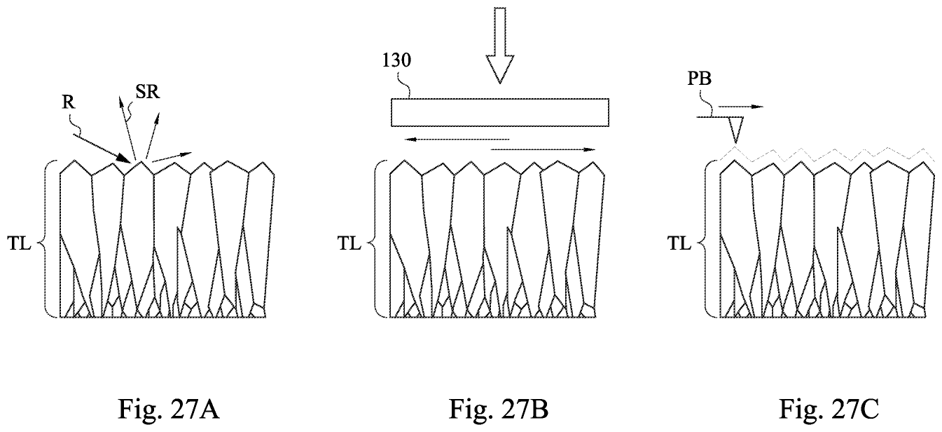

FIGS. 27A, 27B, and 27C illustrate different methods for detecting surface roughness of a target layer in accordance with some embodiments of the present disclosure. FIG. 27A illustrates detecting surface roughness of the target layer TL using dark field inspection. In such embodiments, the CMP endpoint detectors 910 and/or 920 may include a dark field inspection apparatus. The dark field inspection includes generating a radiation R (such a laser beam) on the surface of the target layer TL, and the scattered radiation SR scattered from the surface of the target layer TL is received by a sensor (not shown). The intensity of scattered radiation SR may increase when the surface roughness increases, while the intensity of scattered radiation SR may decrease when the surface roughness decreases. As a result, the intensity of scattered radiation SR may correspond to the surface roughness of the target layer TL. Accordingly, the “pre-determined condition” as discussed above may include the intensity of scattered radiation SR of the polished target layer TL is less than a threshold value. In other embodiments, the “pre-determined condition” may include the difference between the initial intensity of scattered radiation SR of the target layer TL and the intensity of scattered radiation SR of the polished target layer TL is less than a threshold value.

FIG. 27B illustrates detecting surface roughness of the target layer TL using torque signal measurement. In such embodiments, the CMP endpoint detector 920 may include a torque signal measurement apparatus. Since the torque is proportional to the amount of friction between the surface of the target layer TL and the polishing pad 130, surface conditions of the surface of the target layer TL or the polishing pad may be determined from the measured torque by the CMP endpoint detector 920. In some embodiments, the controller (e.g., controller 150) may press the polishing pad 130 against the target layer TL, so as to generate the down-force applied to the target layer TL. During the CMP process, the torque of the polishing pad 130 (or the pad holder 120) is measured by the controller 150. The torque may increase when the surface roughness increases, while the torque may decrease when the surface roughness decreases. As a result, the torque may correspond to the surface roughness of the target layer TL. Accordingly, the “pre-determined condition” as discussed above may include the torque of the polishing pad 130 (or the pad holder 120) is less than a threshold value.

FIG. 27C illustrates detecting surface roughness of the target layer TL using surface probing. In such embodiments, the CMP endpoint detectors 910 and/or 920 may include a surface probing apparatus. The surface probing includes moving a probe PB along the surface of the target layer TL, so as to generate a surface profile of the target layer TL. That is, the surface roughness of the target layer TL can be directly measured using surface probing.

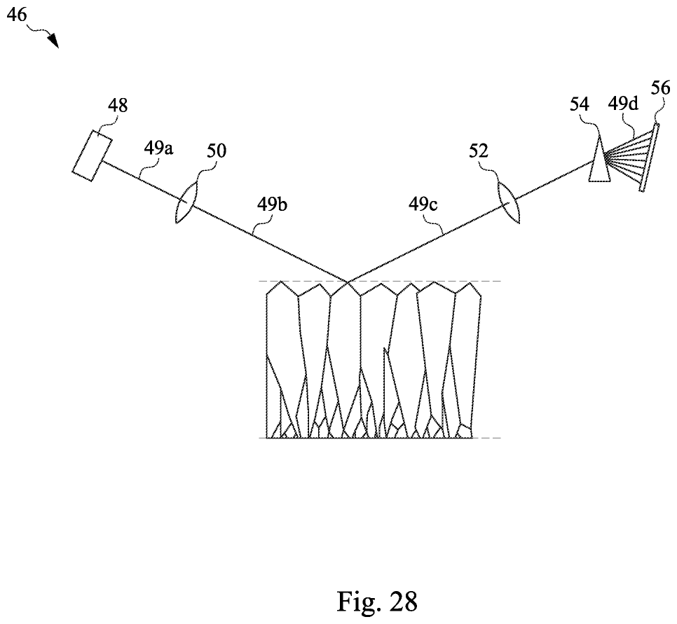

FIG. 28 illustrates a method for detecting thickness of a target layer in accordance with some embodiments of the present disclosure. FIG. 28 illustrates detecting thickness of the target layer TL using spectroscopic ellipsometry. In such embodiments, the CMP endpoint detectors 910 and/or 920 may include a spectroscopic ellipsometry apparatus 46. Spectroscopic ellipsometry technique is widely used for thin film metrology in the semiconductor industry. The spectroscopic ellipsometry apparatus 46 includes a light source 48 which emits a beam of incident light 49a through a rotating polarizer 50, which polarizes the incident light 49a. Polarized light 49b emerges from the rotating polarizer 50 and strikes the object of interest, which is, in this case, the target layer TL. The polarized light 49b is reflected from the target layer TL as reflected light 49c, which passes through an analyzer 52 and a prism 54, respectively. The prism 54 separates the reflected light 49c into a light spectrum 49d. The light spectrum 49d strikes an array detector 56. A computer (not shown), having a monitor screen, is connected to the array detector 56. The computer is provided with supporting software which enables the computer to plot the degree of polarization versus the wavelength of the reflected light 49c reflected from the object of interest, based on the light spectrum 49d that strikes the array detector 56. The thickness of the target layer TL can be calculated based on the change of light polarization. For example, the thickness of the target layer TL can be calculated based on the difference between the light polarization of the incident light 49a and the light polarization of the reflected light 49c.

In some embodiments, the thickness of the target layer TL can also be determined using spectroscopic reflectometry or white light interferometry. In spectroscopic reflectometry, the thickness of the target layer TL is measured based on the change of light intensity. For example, the thickness of the target layer TL can be calculated based on the difference between the light density of the incident light incident on the surface of the target layer TL the and the density of the reflected light reflected from the surface of the target layer TL. In white light interferometry, the thickness of the target layer TL is measured based on the phase difference of the interferograms.

High kappa material CMP require proper endpoint detection, including targeted roughness and thickness measurements including but not limited to optical, fraction, and direct roughness measurements. In the present disclosure, during a CMP process, surface roughness and/or thickness of the layer is measured, and the CMP process can be stopped when the surface roughness and/or thickness of the layer reach a predetermined value, this will be beneficial to improve the device performance.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the surface treatment helps the efficiency of polishing process because the surface treatment modifies the material property (e.g., soft) of the layer intended to be polished. Therefore, the layer intended to be polished can be polished easily even though the layer is a hard material (e.g., diamond), and the polishing pad is not damaged or consumed too much during the polishing process. Another advantage is that during a CMP process, surface roughness and/or thickness of the layer is measured, and the CMP process can be stopped when the surface roughness and/or thickness of the layer reach a predetermined value.

In some embodiments of the present disclosure, a method includes providing a wafer including a layer; performing a surface treatment to the layer; polishing the layer using a polishing pad; determining whether a surface roughness or a thickness of the layer reaches a pre-determined condition; and stopping polishing the layer when the surface roughness or the thickness of the layer reaches the pre-determined condition.

In some embodiments, determining whether the surface roughness or the thickness of the layer reaches the pre-determined condition is performed after performing the surface treatment.

In some embodiments, the surface roughness of the layer is determined based on dark field inspection, torque signal measurement, or surface probing.

In some embodiments, the thickness of the layer is determined based on spectroscopic ellipsometry, spectroscopic reflectometry, or white light interferometry.

In some embodiments, determining whether the surface roughness or the thickness of the layer reaches the pre-determined condition is performed using a CMP endpoint detector, and the CMP endpoint detector is separated from the polishing pad.

In some embodiments, determining whether the surface roughness or the thickness of the layer reaches the pre-determined condition is performed using a CMP endpoint detector, and the CMP endpoint detector is integrated with the polishing pad.

In some embodiments, the pre-determined condition comprises the surface roughness of the layer is less than a threshold value or the thickness of the layer is less than a threshold value.

In some embodiments of the present disclosure, a method includes providing a wafer comprising a device layer, a front-side interconnect structure over the device layer, a backside interconnect structure under the device layer, and a heat dissipation layer over the front-side interconnect structure, wherein the heat dissipation layer is made of diamond; polishing the heat dissipation layer using a polishing pad; determining whether a surface roughness of the heat dissipation layer is less than a first threshold value or a thickness of the heat dissipation layer is less than a second threshold value; and stopping polishing the layer when the surface roughness of the heat dissipation layer is less than the first threshold value or the thickness of the heat dissipation layer is less than the second threshold value.

In some embodiments, the method further includes performing a surface treatment to the heat dissipation layer prior to determining whether the surface roughness or the thickness of the heat dissipation layer reaches the pre-determined condition.

In some embodiments, the surface roughness of the heat dissipation layer is determined based on a light scattering on a polished surface of the heat dissipation layer or a torque of the polishing pad.

In some embodiments, the thickness of the heat dissipation layer is determined based on change of light polarization, change of light intensity, or phase difference of interferograms.

In some embodiments, determining whether the surface roughness of the heat dissipation layer is less than the first threshold value is performed using a first CMP endpoint detector.

In some embodiments, determining whether the thickness of the heat dissipation layer is less than the second threshold value is performed using a second CMP endpoint detector, separated from the first CMP endpoint detector.

In some embodiments, the first CMP endpoint detector is integrated with the polishing pad, and the second CMP endpoint detector is separated from the polishing pad.

In some embodiments of the present disclosure, a polishing apparatus includes a platen configured to secure a wafer. A pad holder is over the platen and configured to hold a polishing pad. A beam device is over the platen and configured to emit a beam toward a layer over the wafer. A first endpoint detector is configured to measure a surface roughness or a thickness of the layer over the wafer.

In some embodiments, the first endpoint detector is integrated with the pad holder.

In some embodiments, the first endpoint detector is separated from the pad holder.

In some embodiments, the polishing apparatus further includes a second endpoint detector, wherein the first endpoint detector is configured to measure the surface roughness of the layer over the wafer, and the second endpoint detector is configured to measure the surface roughness of the layer over the wafer.

In some embodiments, the first endpoint detector is integrated with the pad holder, and the second endpoint detector is separated from the pad holder.

In some embodiments, the beam device and the first endpoint detector are integrated with the pad holder.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a wafer including a layer;
performing a surface treatment to the layer;
polishing the layer using a polishing pad;
determining whether a surface roughness or a thickness of the layer reaches a pre-determined condition; and
stopping polishing the layer when the surface roughness or the thickness of the layer reaches the pre-determined condition.

2. The method of claim 1, wherein determining whether the surface roughness or the thickness of the layer reaches the pre-determined condition is performed after performing the surface treatment.

3. The method of claim 1, wherein the surface roughness of the layer is determined based on dark field inspection, torque signal measurement, or surface probing.

4. The method of claim 1, wherein the thickness of the layer is determined based on spectroscopic ellipsometry, spectroscopic reflectometry, or white light interferometry.

5. The method of claim 1, wherein determining whether the surface roughness or the thickness of the layer reaches the pre-determined condition is performed using a CMP endpoint detector, and the CMP endpoint detector is separated from the polishing pad.

6. The method of claim 1, wherein determining whether the surface roughness or the thickness of the layer reaches the pre-determined condition is performed using a CMP endpoint detector, and the CMP endpoint detector is integrated with the polishing pad.

7. The method of claim 1, wherein the pre-determined condition comprises the surface roughness of the layer is less than a first threshold value or the thickness of the layer is less than a second threshold value.

8. A method comprising:
providing a wafer comprising:
a device layer;
a front-side interconnect structure over the device layer;
a backside interconnect structure under the device layer; and
a heat dissipation layer over the front-side interconnect structure, wherein the heat dissipation layer is made of diamond;
polishing the heat dissipation layer using a polishing pad;
determining whether a surface roughness of the heat dissipation layer is less than a first threshold value or a thickness of the heat dissipation layer is less than a second threshold value; and
stopping polishing the heat dissipation layer when the surface roughness of the heat dissipation layer is less than the first threshold value or the thickness of the heat dissipation layer is less than the second threshold value.

9. The method of claim 8, further comprising performing a surface treatment to the heat dissipation layer prior to determining whether the surface roughness of the heat dissipation layer is less than the first threshold value or the thickness of the heat dissipation layer is less than the second threshold value.

10. The method of claim 8, wherein the surface roughness of the heat dissipation layer is determined based on a light scattering on a polished surface of the heat dissipation layer or a torque of the polishing pad.

11. The method of claim 8, wherein the thickness of the heat dissipation layer is determined based on change of light polarization, change of light intensity, or phase difference of interferograms.

12. The method of claim 8, wherein determining whether the surface roughness of the heat dissipation layer is less than the first threshold value is performed using a first CMP endpoint detector.

13. The method of claim 12, wherein determining whether the thickness of the heat dissipation layer is less than the second threshold value is performed using a second CMP endpoint detector, separated from the first CMP endpoint detector.

14. The method of claim 13, wherein the first CMP endpoint detector is integrated with the polishing pad, and the second CMP endpoint detector is separated from the polishing pad.

15. A polishing apparatus comprising:
a platen configured to secure a wafer;
a pad holder over the platen and configured to hold a polishing pad;
a beam device over the platen and configured to emit a beam toward a layer over the wafer; and
a first endpoint detector configured to measure a surface roughness or a thickness of the layer over the wafer.

16. The polishing apparatus of claim 15, wherein the first endpoint detector is integrated with the pad holder.

17. The polishing apparatus of claim 15, wherein the first endpoint detector is separated from the pad holder.

18. The polishing apparatus of claim 15, further comprising a second endpoint detector, wherein the first endpoint detector is configured to measure the surface roughness of the layer over the wafer, and the second endpoint detector is configured to measure the surface roughness of the layer over the wafer.

19. The polishing apparatus of claim 18, wherein the first endpoint detector is integrated with the pad holder, and the second endpoint detector is separated from the pad holder.

20. The polishing apparatus of claim 15, wherein the beam device and the first endpoint detector are integrated with the pad holder.
